(19) United States
(12) Patent Application Publication
(10) Pub. No.: US 2025/0391790 A1
(43) Pub. Date: Dec. 25, 2025

(54) SPARK GAP STRUCTURES AND METHODS IN AN INTEGRATED CIRCUIT DEVICE

(71) Applicant: Allegro MicroSystems, LLC, Manchester, NH (US)

(72) Inventors: Maxim Klebanov, Palm Coast, FL (US); Felix Palumbo, Buenos Aires (AR); Washington Lamar, Mont Vernon,, NH (US); Sagar Saxena, Manchester, NH (US); Yash Shaileshbhai Patel, Manchester, NH (US)

(73) Assignee: Allegro MicroSystems, LLC, Manchester, NH (US)

(21) Appl. No.: 18/752,924

(22) Filed: Jun. 25, 2024

(51) Int. Cl. H01L 23/60; H01L 23/48; H01T 1/14; H02H 9/06

(52) U.S. Cl. CPC H01L 23/60; H01L 23/481; H01T 1/14; H02H 9/06

(57) ABSTRACT

Apparatus includes a substrate, a metal layer over the substrate, and a passivation layer over the metal layer. The metal layer includes a first metal portion coupled to a first bond pad and having a first terminal end and a second metal portion coupled to a second bond pad and having a second terminal end spaced from the first terminal end by a gap configured to form a spark gap between the first terminal end and the second terminal end. The apparatus may additionally or alternatively include a first die having a first ground contact and a first Through Silicon Via (TSV) and a second die having a second ground contact that is galvanically isolated from the first ground contact and a second TSV with the first TSV and the second TSV vertically aligned to form a second spark gap between the first die and the second die.

### BACKGROUND

Electronic devices sometimes operate in environments that can damage the components and devices. Installation of a device in an automobile, for example, can expose electronic devices to stress conditions that can cause damage to the part. Also, static charge that has built up can transfer to the electronic device during handling, installation, or inspection. Devices can also be damaged by interruptions or fluctuations in power to which the device is connected.

In general, electronic devices may be subject to electrical overstress (“EOS”) conditions, such as an electrostatic discharge (“ESD”) event occurring between exposed pins or leads or pads of the device. These events can occur if there is a system fault or if the electronic device is exposed to an external charge. For example, the human body can store a charge that can correlate to a voltage as high as 25 kV. If a charged body touches an external lead of the electronic device, that charge can be transferred to and potentially damage the device.

In electronic devices containing more than one semiconductor die, the die are generally electrically isolated from each other. Unpredictable discharge paths can result from such galvanic isolation that can cause electrical current to arc between the die and potentially damage the electronic device. For example, discharge paths can include pin-to-pin arcing and/or dielectric breakdown of mold compound and/or die attach adhesive.

During manufacturing, devices generally undergo human-body model (HBM) testing to characterize susceptibility of the device to damage from ESD. Many devices contain ESD protection circuits that provide paths for current due to ESD events to flow without damaging the internal circuitry of the device.

### SUMMARY

The present disclosure is directed to circuits and methods for providing a spark gap in an integrated circuit device. The spark gap can be provided between terminal portions of a top metal layer and/or between through silicon vias (TSVs). The spark gap is designed to permit charge to conduct under predetermined breakdown voltage conditions selected to protect electronic circuitry within the device.

According to the disclosure, apparatus includes a substrate, a metal layer disposed over the substrate and including a first metal portion coupled to a first bond pad and having a first terminal end and a second metal portion coupled to a second bond pad and having a second terminal end spaced from the first terminal end by a gap configured to form a spark gap between the first terminal end and the second terminal end, and a passivation layer disposed over the metal layer.

Features may include one or more of the following individually or in combination with other features. The passivation layer can have an opening configured to expose the first terminal end and the second terminal end to air, wherein the spark gap extends through air. The spark gap can extend through a portion of the passivation layer disposed between the first terminal end and the second terminal end. The metal layer can include a plurality of metal layers including a top metal layer positioned further from the substrate than the other metal layers, wherein the first metal portion and the second metal portion are portions of the top metal layer. The first terminal end can have a first point and the second terminal end can have a second point. The first terminal end can have a plurality of first points and the second terminal end can have a plurality of second points, wherein each of the first points is spaced from a respective second point by a gap configured to form a spark gap between the respective first point and second point. At least two of the gaps between first and second points can have different lengths. The first terminal end can have a first rounded edge and the second terminal end can have a second rounded edge. The first terminal end can have a plurality of first rounded edges and the second terminal end can have a plurality of second rounded edges, wherein each of the first rounded edges is spaced from a respective second rounded edge by a gap configured to form a spark gap between the respective first and second rounded edges. At least two of the gaps between first and second rounded edges can have different lengths. The first terminal end can have a point and the second terminal end can have a concave edge. The apparatus can include an integrated circuit package and the substrate can include a semiconductor die. The first metal portion can be attached to a first bond pad of the integrated circuit package and the second metal portion can be attached to a second bond pad of the integrated circuit package.

In embodiments, the spark gap can include a first spark gap and wherein the substrate can include a first die having a first ground contact and a first Through Silicon Via (TSV) extending from a top surface of the first die to a bottom surface of the first die, and a second die having a second ground contact that is galvanically isolated from the first ground contact and having a second TSV extending from a top surface of the second die to a bottom surface of the second die, wherein the first TSV and the second TSV are vertically aligned to form a second spark gap between the first die and the second die. An adhesive layer can be provided between the bottom surface of the first die and the top surface of the second die. In some embodiments, the adhesive layer can be disposed between the first TSV and the second TSV. In other embodiments, the adhesive layer is not disposed between the first TSV and the second TSV.

According to the disclosure, apparatus includes a first die having a first ground contact and a first Through Silicon Via (TSV) extending from a top surface of the first die to a bottom surface of the first die and a second die having a second ground contact that is galvanically isolated from the first ground contact and a second TSV extending from a top surface of the second die to a bottom surface of the second die, wherein the first TSV and the second TSV are vertically aligned to form a spark gap between the first die and the second die.

Features may include one or more of the following individually or in combination with other features. An adhesive layer can be provided between the bottom surface of the first die and the top surface of the second die. In some embodiments, the adhesive layer can be disposed between the first TSV and the second TSV. In other embodiments, the adhesive layer is not disposed between the first TSV and the second TSV.

Also described is a method for protecting an integrated circuit from electrostatic discharge including providing a substrate, providing a metal layer over the substrate with a first metal portion coupled to a first bond pad and having a first terminal end and a second metal portion coupled to a second bond pad and having a second terminal end spaced from the first terminal end by a gap configured to form a spark gap between the first terminal end and the second terminal end, and providing a passivation layer over the metal layer.

Features may include one or more of the following individually or in combination with other features. The method can include forming an opening in the passivation layer to expose the first terminal end and the second terminal end to air, wherein the spark gap extends through air. The spark gap can extend through a portion of the passivation layer disposed between the first terminal end and the second terminal end.

Also described is a method for protecting a multi-die electronic device from electrostatic discharge including providing a first die having a first ground contact and a first TSV extending from a top surface of the first die to a bottom surface of the first die, providing a second die having a second ground contact that is galvanically isolated from the first ground contact and a second TSV extending from a top surface of the second die to a bottom surface of the second die, and attaching a second die to the first die so that the first TSV is vertically aligned with the second TSV to form a spark gap between the first die and the second die.

Features may include one or more of the following individually or in combination with other features. The method may include providing an adhesive layer between the first die and the second die. The method may include monitoring a thickness of the adhesive layer based on a breakdown voltage that causes an arc across the spark gap.

According to the disclosure, apparatus includes a substrate, a bottom metal layer disposed over the substrate, a top metal layer disposed over the bottom metal layer and including a first metal portion coupled to a first bond pad and having a first terminal end and a second metal portion coupled to a second bond pad and having a second terminal end spaced from the first terminal end by a gap, a dielectric layer between the top metal layer and the bottom metal layer, a first via between the first metal portion of the top metal layer and the bottom metal layer and including a metal via portion and a dielectric via portion, a second via between the second metal portion of the top metal layer and the bottom metal layer and including a metal via portion and a dielectric via portion, and a passivation layer disposed over the top metal layer.

### BRIEF DESCRIPTION OF DRAWINGS

The foregoing features may be more fully understood from the following description of the drawings. The drawings aid in explaining and understanding the disclosed technology. Since it is often impractical or impossible to illustrate and describe every possible embodiment, the provided figures depict one or more illustrative embodiments. Accordingly, the figures are not intended to limit the scope of the broad concepts, systems and techniques described herein. Like numbers in the figures denote like elements.

FIG. 1 is a side view of an integrated circuit device including a spark gap according to the disclosure;

FIG. 1A is a plan view of the device of FIG. 1 according to the disclosure;

FIG. 1B is a plan view of an integrated circuit device including a spark gap according to the disclosure;

FIG. 1C is a plan view of an integrated circuit device including a spark gap according to the disclosure;

FIG. 2 is a plan view of an integrated circuit device including a spark gap according to the disclosure;

FIG. 3 is a plan view of an integrated circuit device including a spark gap according to the disclosure;

FIG. 4 is a plan view of an integrated circuit device including a spark gap according to the disclosure;

FIG. 5 is a perspective exploded view of a multi-die integrated circuit device including a spark gap according to the disclosure;

FIG. 6 is a side view of a multi-die integrated circuit device including a spark gap according to the disclosure;

FIG. 7 is a perspective view of an integrated circuit device including a spark gap according to the disclosure; and

FIG. 8 is a side view of an integrated circuit device including a spark gap according to the disclosure.

### DETAILED DESCRIPTION

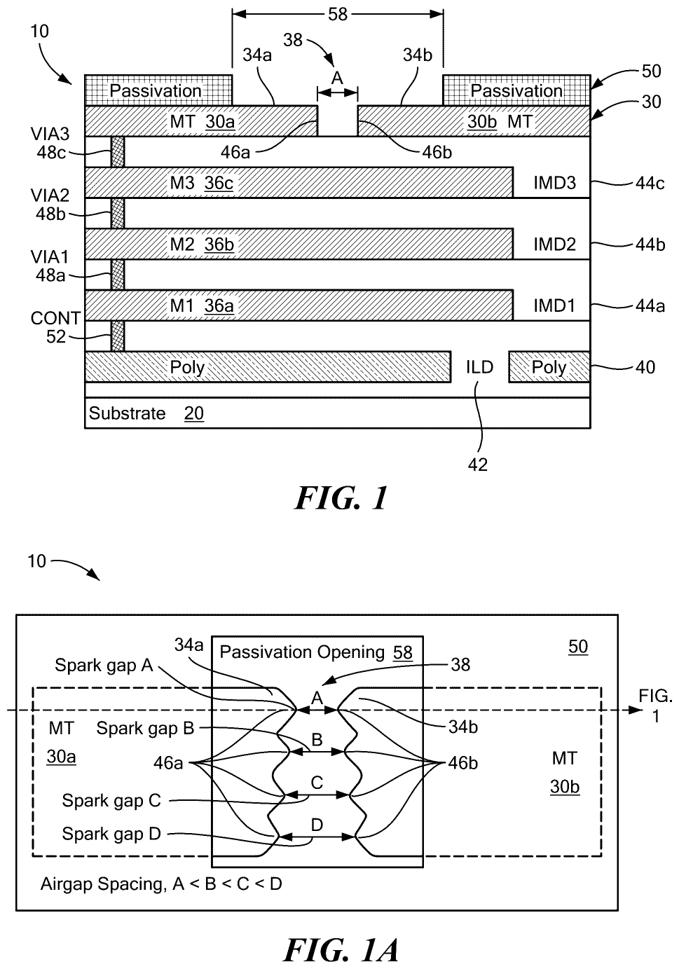

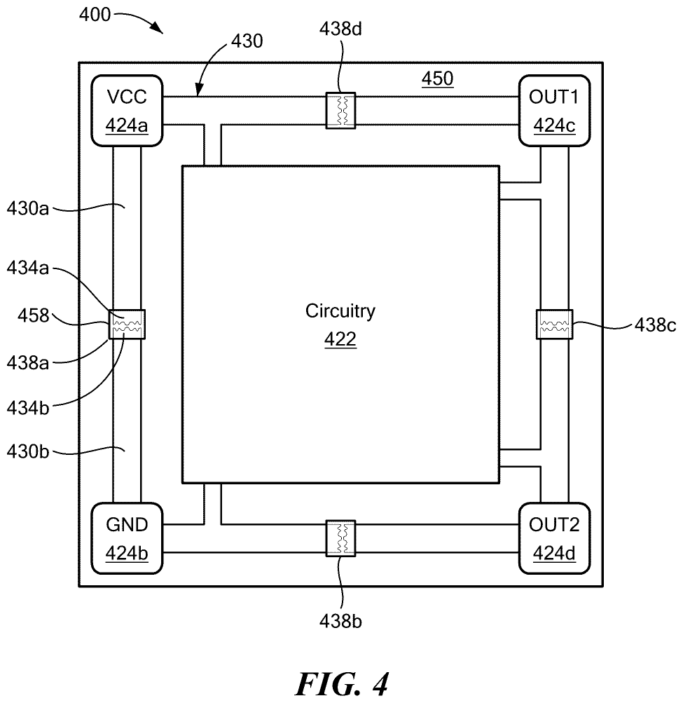

Referring to FIG. 1, a cross-sectional side view of an integrated circuit device 10 shows a substrate 20 and a metal layer 30 disposed over the substrate. The metal layer 30 includes a first metal portion 30a configured to be coupled to a first bond pad (e.g., as shown in FIG. 4) and having a first terminal end 34a and a second metal portion 30b configured to be coupled to a second bond pad (e.g., as shown in FIG. 4) and having a second terminal end 34b spaced from the first terminal end by a gap 38 having a length labeled “A”. The gap 38 forms a spark gap between the first terminal end 34a of the first metal portion 30a and the second terminal end 34b of the second metal portion 30b.

It will be appreciated by those of ordinary skill in the art that unpredictable conduction paths can occur in device 10 that can result in excess charge damaging the device. For example, bond pads to which the first and second metal portions 30a, 30b are coupled can be subjected to external sources of charge and arcing can result to and/or between such bond pads. Electronic circuitry supported by substrate 20 can include ESD protective elements, such as clamps; however, certain conditions and conduction paths can bypass such protective devices causing damage to device 10.

In the context of the subject disclosure, “spark gap” refers to a space or gap between generally adjacent or proximate elements or element portions that is designed to allow a transient charge in the form of an electric spark to pass between the elements or element portions. In the example of FIG. 1, such adjacent element portions are the first terminal end 34a of the first metal portion 30a and the second terminal end 34b of the second metal portion 30b and the gap 38 between such terminal ends can be referred to herein interchangeably as spark gap 38.

In use, when the voltage between the terminal ends 34a, 34b reaches a breakdown voltage of the medium between the terminal ends, such as air, current flows between the terminal ends through spark gap 38 and continues to flow until the voltage drops to below the breakdown voltage. Thus, with the described spark gap 38, a path is provided across the spark gap, through which current can flow under certain ESD types of conditions. Without the spark gap 38, current could flow internally to device 10 and potentially damage the device. In this way, spark gap 38 can prevent or reduce the chance of an electrical arc within the device, and thus prevent or reduce the chance of damage to circuitry supported by the substrate 20 due to arcing or heat.

Metal layer 30 can be referred to as a top metal layer, MT, in the sense that it is the top-most metal layer of one or more metal layers disposed over substrate 20. In the embodiment of FIG. 1, device 10 includes four metal layers including a first metal layer M1 36a, a second metal layer M2 36b, a third metal layer M3 36c, and top metal layer MT 30, as shown.

Metal layers 30, 36a, 36b, and 36c can be comprised of various materials, such as aluminum and can have varying thicknesses, such as a thickness on the order of 0.5 μm. The materials and thicknesses of the metal layers 36a, 36b, 36c, and 30 can be the same or different than each other. Geometries of metal layers 30, 36a, 36b, and 36c are designed according to circuit and application requirements.

Dielectric layers 44a, 44b, 44c are disposed between each of the metal layers 30, 36a, 36b, and 36c, as shown, and may be referred to as intermetal dielectric (IMD) layers. Layers 44a, 44b, 44c can be comprised of various materials, such as FSaG/SiO₂.

A polysilicon layer 40 can separate the substrate 20 from the lowest-most metal layer 36a and an interlayer dielectric (ILD) 42 can insulate the substrate 20 from other layers, as shown. Polysilicon layer 40 can be coupled to the first metal layer 36a by a contact element 52 and vias 48a, 48b, 48c can be coupled between the metal layers 36a, 36b, 36c, as shown. Vias 48a, 48b, 48c can be filled or hollow metal cylinders that extend between and electrical couple the layers to which they are attached.

A protective passivation layer 50 is disposed over the top metal layer 30. Passivation layer 50 has an opening 58 that is configured to expose the terminal ends 34a, 34b of the first and second metal portions 30a, 30b, respectively. In this way, the medium through which charge passes between terminal ends 34a, 34b of first and second metal portions 30a, 30b, respectively is air which can have a breakdown on the order of approximately 30 kV/cm at 1 ATM (i.e., at sea level) for spark conduction.

In other embodiments, passivation layer 50 may not have an opening, in which case the spark conduction is through the passivation layer material.

By design of the first and second metal portions 30a, 30b and their respective terminal ends 34a, 34b, spark gap 38 is configured to permit charge to conduct under predetermined breakdown voltage conditions selected to protect electronic circuitry supported by substrate 20. Material properties and geometries of terminal ends 34a, 34b affect the breakdown voltage. Breakdown voltage is also affected by environmental conditions such as temperature and gas pressure. Spark gap design can include empirical techniques to plot breakdown voltage values for different spark gap lengths “A”, for example from 4 μm to 15 um.

In embodiments, the substrate 20 is a semiconductor substrate and the spark gap 38 can be manufactured down to the minimum metal spacing allowed by the back-end-of-line (BEOL) semiconductor technology (i.e., the minimum spacing allowed by lithography, clean room dust particles, glass mask defects, etc.). For example, BEOL minimum spacing, for 180 nm technology, typically can be approximately 4 μm and thus, the minimum spark gap length “A” can be on the order of 4 μm in some embodiments.

Referring to FIG. 1A, a top plan view of device 10 is shown. From the top view, the terminal ends 34a, 34b or metal portions 30a, 30b are visible through the opening 58 in passivation layer 50. The terminal end 34a of first metal portion 30a has a plurality of first points 46a and the terminal end 34b of second metal portion 30b has a plurality of second points 46b. Each of the first points 46a is substantially directly across and spaced from a respective second point 46b by a gap (labelled as gaps A, B, C, and D) configured to form a spark gap between the respective first point and second point. Thus, the illustrated spark gap 38 can be considered to include four spark gaps A, B, C, D. By “directly across” it means that the respective gap lengths A, B, C, D represent the shortest lengths between each respective set of points 46a, 46b.

At least two of the gaps A, B, C, D between first points 46a and second points 46b can have different lengths and, in the illustrated example, each of the gaps A, B, C, D has a different length. Example lengths for gaps A, B, C, D can range from “minimum” lengths determined by technology constraints to “maximum” lengths determined by ESD specifications and spark gap materials.

In the illustrated example, spark gap lengths A, B, C, and D are increasing such that A<B<C<D. In some embodiments, this spacing scheme allows spark gap A (minimum gap space) to arc and conduct for the first ESD event. In the event that spark gap A is damaged, the next shortest air gap, spark gap B, would act as next viable spark gap. Similarly, spark gap C would conduct if spark gap B is damaged and so on. In some embodiments, more than one such spark gap A, B, C, D can arc and conduct for a single ESD event.

It will be appreciated by those of ordinary skill in the art that the example spark gap 38 with individual spark gaps A, B, C, D is an example only and the disclosure is not limited to the particular number of individual gaps making up spark gap 38 or the geometry of the spark gaps A, B, C, D having points 46a, 46b arranged as shown. For example, spark gaps A, B, C, D forming spark gap 38 are not limited to any particular length or relationship between lengths. Also, the extent of points 46a, 46b (e.g., radius of the tip of the points), like the material properties of the metal layer 30 and other geometrical aspects such as thickness, can be varied to suit desired breakdown voltages for the spark gap to conduct.

FIGS. 1B and 1C illustrate alternative top plan views of device 10 according to different designs of spark gap 38.

Referring to FIG. 1B, an alternative top plan view of device 10 is shown from which the terminal ends 34a, 34b of metal portions 30a, 30b are visible through the opening 58 in passivation layer 50. The terminal end 34a of first metal portion 30a has a plurality of first points 56a and the terminal end 34b of second metal portion 30b has a plurality of second points 56b, with each of the first points 56a substantially directly across and spaced from a respective second point 56b by a gap (labelled as gaps C, B, A, B, C). Each gap C, B, A, B, C is configured to form a spark gap between the respective first point 56a and second point 56b. Thus, in the embodiment of FIG. 1B, spark gap 38 includes five spark gaps arranged as gaps C, B, A, B, C.

As with other spark gap designs, the geometries of first points 56a and second points 56b and other attributes can be varied to suit application requirements.

In the illustrated example, each gap A, B, C has a different length. Spark gap spacings A, B, C are designed with increasing distances such that A<B<C. In some embodiments, this spacing scheme allows spark gap A (minimum gap space) to arc and conduct for the first ESD event. In the event that spark gap A is damaged, the next two shortest air gaps, spark gaps B, would act as next viable spark gaps. Similarly, spark gaps C would conduct if spark gaps B are damaged. In some embodiments, more than one such spark gap A, B, C can arc and conduct for a single ESD event.

Referring to FIG. 1C, another alternative top plan view of device 10 is shown from which the terminal ends 34a, 34b of metal portions 30a, 30b are visible through the opening 58 in passivation layer 50. The terminal end 34a of first metal portion 30a has a plurality of first rounded ends 66a and the terminal end 34b of second metal portion 30b has a plurality of second rounded ends 66b, with each first rounded end 66a substantially directly across and spaced from a respective second rounded end 66b by a gap (labelled as gaps C, B, A, B, C). Each gap C, B, A, B, C is configured to form a spark gap between the respective first rounded end 66a and second rounded end 66b. Thus, in the embodiment of FIG. 1C, spark gap 38 includes five spark gaps arranged as gaps C, B, A, B, C.

As with other spark gap designs, the geometries of first rounded ends 66a and second rounded ends 66b and other attributes can be varied to suit application requirements. For example, the radius of the rounded ends 66a, 66b can be made larger or smaller than the illustrated example and can be the same as or different than each other.

In the illustrated example, each gap A, B, C has a different length. Spark gap spacings A, B, and C are designed with increasing distances such that A<B<C. In some embodiments, this spacing scheme allows spark gap A (minimum gap space) to arc and conduct for the first ESD event. In the event that spark gap A is damaged, the next two shortest air gaps, spark gaps B, would act as next viable spark gaps. Similarly, spark gaps C would conduct if spark gaps B are damaged, and so on. In some embodiments, more than one such spark gap A, B, C can arc and conduct for a single ESD event.

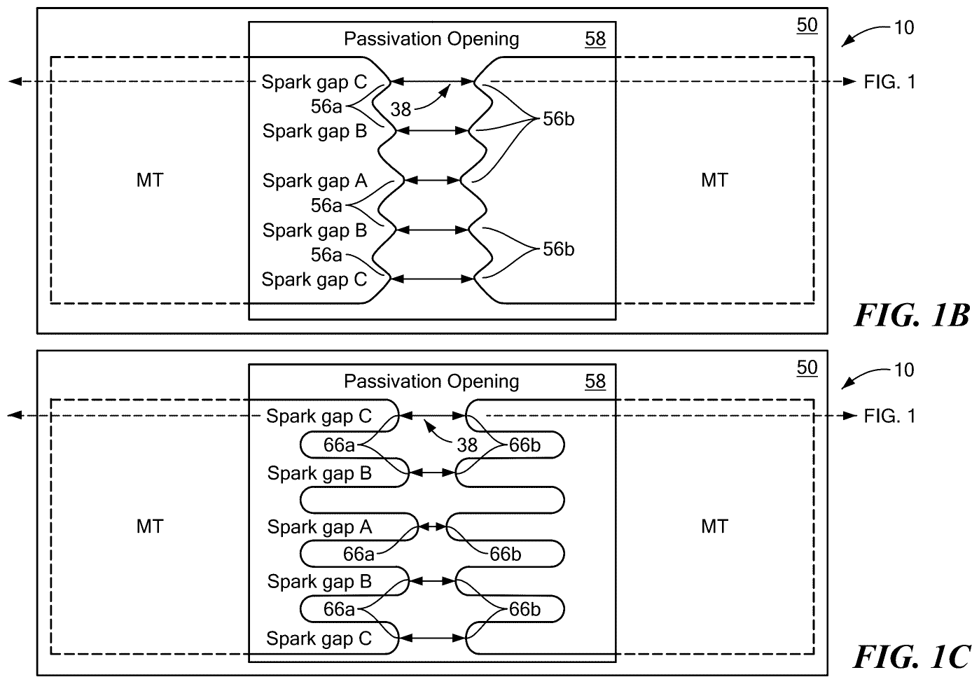

Referring to FIG. 2, a top plan view of another example spark gap 238 is shown. Spark gap 238 can be formed by a gap in a top metal layer 230 that can be similar to top metal layer 30 of FIG. 1 and thus, that has a first metal portion 230a and a second metal portion 230b. Terminal ends 234a, 234b of respective metal portions 230a, 230b are visible through an opening 258 in a passivation layer 250.

First terminal end 234a of first metal portion 230a can be configured to be coupled to a first bond pad (e.g., as shown in FIG. 4) and second terminal end 234b of second metal portion 230b can be configured to be coupled to a second bond pad (e.g., as shown in FIG. 4). Passivation layer 250 can be disposed over the top metal layer 230 and can have an opening 258 that can be the same as or similar to opening 58 of passivation layer 50 of FIG. 1.

Like the terminal ends 34a, 34b of the spark gap 38 of FIG. 1A, in the spark gap 238 of FIG. 2, the first terminal end 234a has a plurality of first points 246a and the second terminal end 234b has a plurality of second points 246b. However, spark gap 238 differs from spark gap 38 in that the first points 246a are not directly across from second points 246b. Rather, the first points 246a are offset from, or staggered, or provided with a zig-zag pattern with respect to the second points 246b, as shown.

Terminal ends 234a, 234b can have first edges 248a flanking each first point 246a and second edges 248b flanking each second point 246b.

The illustrated spark gap 238 can form a first spark gap D1, a second spark gap D2, and a third spark gap D3, each associated with a different conduction path type. For example, spark gap D1 permits conduction from first point 246a to an adjacent second point 246b, spark gap D2 permits conduction from a first edge 248a to an opposing second edge 248b, and a spark gap D3 permits conduction from a first point 246a to an adjacent second edge 248b.

Points 246a, 246b and edges 248a, 248b of terminal ends 234a, 234b, respectively, can be arranged such that the first spark gap D1 has a largest length, the second spark gap D2 has a next largest length, and third spark gap D3 has the smallest length, as shown. The lengths of spark gaps D1, D2, D3 can be designed to vary the breakdown voltage that will result in conduction and overall optimize and enhance performance. In other words, spark gaps D1, D2, and D3 are designed with decreasing distances such that D1>D2>D3. In some embodiments, this spacing scheme allows spark gap D3 (minimum gap space) to arc and conduct for the first ESD event. In the event that spark gap D3 is damaged, the next longest air gap, spark gaps D2, would act as next viable spark gap. Similarly, spark gap D1 would conduct if spark gaps D3, D2 are damaged. In some embodiments, more than one such spark gap D1, D2, D3 can arc and conduct for a single ESD event.

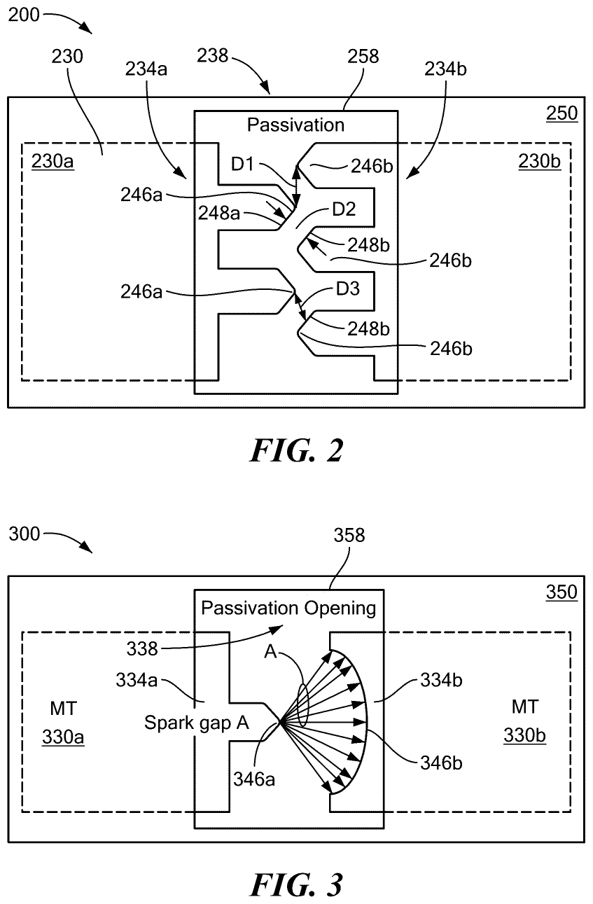

Referring to FIG. 3, a top plan view of another example spark gap 338 is shown. Spark gap 338 can be formed by a gap in a top metal layer 330 that can be similar to top metal layer 30 of FIG. 1 and thus, that has a first metal portion 330a and a second metal portion 330b. Terminal ends 334a, 334b of respective metal portions 330a, 330b are visible through an opening 358 in a passivation layer 350.

First terminal end 334a of first metal portion 330a can be configured to be coupled to a first bond pad (e.g., as shown in FIG. 4) and second terminal end 334b of second metal portion 330b can be configured to be coupled to a second bond pad (e.g., as shown in FIG. 4). Passivation layer 350 can be disposed over the top metal layer 330 and can have an opening 358 that can be the same as or similar to opening 58 of top metal layer 30 of FIG. 1.

The first terminal end 334a of spark gap 338 has a single point 346a and the second terminal end 334b has a generally concave edge 346b. The illustrated spark gap 338 can form a plurality of individual spark gaps, each illustrated by a line “A” that represents the length of each respective spark gap. The geometry of point 346a and the concave edge 346b can yield the plurality of spark gaps A, each having substantially the same length. With this arrangement, there are multiple paths from the single point electrode 346a of the first metal portion 330a to the concave edge 346b of the second metal portion 330b as can facilitate control of the discharge current.

Referring to FIG. 4, a top plan view of an integrated circuit device 400 includes a plurality of spark gaps 438a, 438b, 438c, 438d, each formed in a top metal layer 430 disposed over a substrate. Metal layer 430 includes metal portions configured to be coupled to spark gaps 438a, 438b, 438c, 438d, to bond pads 424a, 424b, 424c, 424d and to circuitry 422 supported by the substrate.

Circuitry 442 can implement various functionality, such as sensor functionality using one or more sensing elements, in combination with other circuits and elements. For example, device 400 can be a magnetic field sensor containing one or more magnetic field sensing elements. The magnetic field sensor can be, for example, a rotation detector, a movement detector, a proximity detector, or a position detector. A linear sensor can sense a magnetic field strength. A rotation detector (or movement detector) can sense passing target objects, for example, magnetic domains of a ring magnet or a ferromagnetic target (e.g., gear teeth) where the magnetic field sensor is used in combination with a back-bias or other magnet and can determine target movement speed and/or direction. Also, linear arrangements of ferromagnetic objects are possible that move linearly.

Bond pads 424a, 424b, 424c, 424d permit electrical connection and probe contact to device 400. Example bond pads include VCC bond pad 424a and GND bond pad 424b through which power is coupled to the device 400. Example bond pad 424c can provide a first output connection OUT1 and example bond pad 424d can provide a second output connection OUT2, with output connection bond pads 424c, 424d permitting communication of device output signals to external circuits and systems. It will be appreciated by those of ordinary skill in the art that the concepts described herein are not limited to any particular device package type or configuration.

As is labeled in connection with example spark gap 438a, metal layer 430 includes a first metal portion 430a configured to be coupled to first bond pad 424a and a second metal portion 430b configured to be coupled to second bond pad 424b. Spark gap 438a can take the form of any of the above-described spark gaps with the first metal portion 430a having a terminal end 434a spaced from a terminal end 434b of the second metal portion 430b by a gap. An opening 458 in a passivation layer 450 can expose the terminal ends 434a, 434b of spark gap 438a.

It will be appreciated that spark gaps 438a, 438b, 438c, 438d can be the same as each other or can be different in design. It will also be appreciated that device 400 is an example only and that the configuration of bond pads 424a, 424b, 424c, 424d, top metal layer 430, and spark gaps 438a, 438b, 438c, 438d can be varied to suit application requirements.

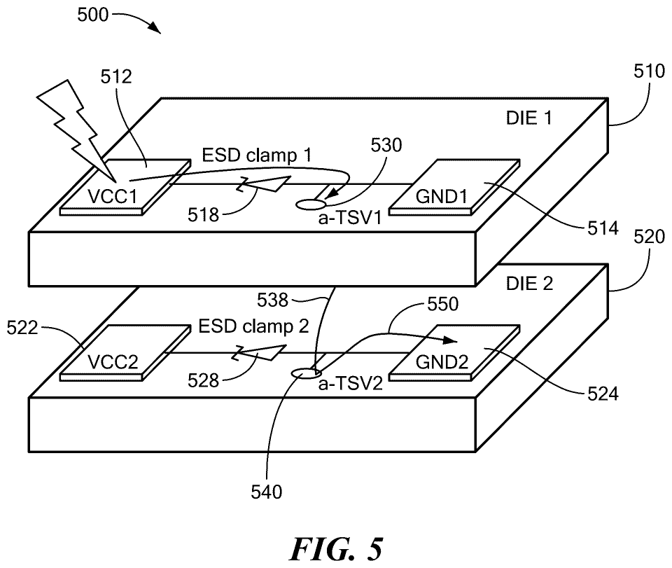

Referring to FIG. 5, a perspective exploded view of a multi-die integrated circuit device 500 includes a spark gap 538 according to a further aspect of the disclosure. Device 500 includes a first die 510 having a first ground contact 514 and a first Through Silicon Via (TSV) 530 extending from a top surface of the first die to a bottom surface of the first die and a second die 520 having a second ground contact 524 that is galvanically isolated from the first ground contact 514 and a second TSV 540 extending from a top surface of the second die to a bottom surface of the second die. More generally, the first and second die 510, 520 are electrically isolated from each other.

Multiple die are sometimes provided in a single package for redundancy purposes, as can be required to meet certain safety requirements, such as ASIL requirements. Accordingly, the die 510, 520 may or may not be identical to each other. Identical circuits on die 510, 520 may act as redundant circuits so that, if one of the circuits malfunctions, the other may continue to operate. Such redundancy is sometimes referred to as homogeneous redundancy. In other embodiments, first and second die 510, 520 support different circuits that may perform the same or different functions and/or with the same or different methodologies and/or with the same or different accuracies. Such redundancy is sometimes referred to as heterogeneous redundancy. It will be appreciated by those of ordinary skill in the art that the devices described herein are not limited to any particular number or configuration of die with the device package.

First die 510 can include at least two bond pads, here shown as a VCC1 bond pad 512 and GND1 bond pad 514. Similarly, second die 520 can include at least two bond pads, here shown as a VCC2 bond pad 522 and GND2 bond pad 524. A first ESD clamp 518 can be provided on the first die 510 between bond pads 512, 514 and a second ESD clamp 528 can be provided on the second die 520 between bond pads 522, 524, as shown.

In assembly, the first TSV 530 and the second TSV 540 are aligned (e.g., vertically aligned) to form a spark gap 538 (represented by a conduction path line labeled 538) between the first die 510 and the second die 520.

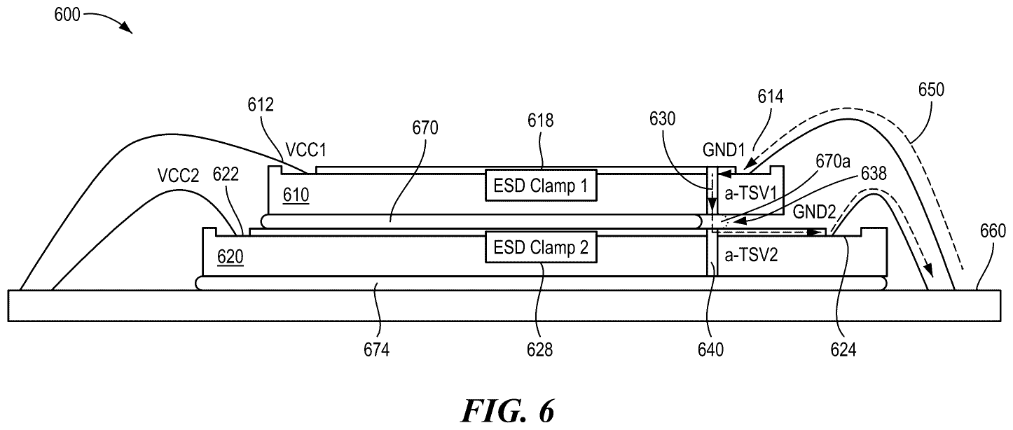

Die 510 and die 520 can be attached to each other with an adhesive layer (see, e.g., adhesive layer 670 in the multi-die embodiment of FIG. 6). As will be explained, adhesive may or may not be disposed between the first and second TSVs 530, 540.

In use, an ESD or other electrical overstress condition can occur (as represented by a thunderbolt arrow at bond pad 512) and by operation of the spark gap 538, current can conduct from the first bond pad 512, through ESD clamp 518, TSV 530, to TSV 540, and out of the IC 500 through bond pad 524. It will be appreciated that other conduction paths are possible of which the illustrated path through spark gap 538 is an example.

Referring also to FIG. 6, an assembled multi-die integrated circuit device 600 includes a spark gap 638 that can be the same as or similar to spark gap 538 of FIG. 5 in that it includes a first TSV 630 through a first die 610 aligned with a second TSV 640 through a second die 620. First die 610 has a first ground contact 614 and first TSV 630 extends from a top surface of the first die to a bottom surface of the first die. Second die 620 has a second ground contact 624 that is galvanically isolated from the first ground contact 614 and second TSV 640 extends from a top surface of the second die to a bottom surface of the second die. More generally, the first and second die 610, 620 are electrically isolated from each other.

First die 610 can include at least two bond pads, here shown as a VCC1 bond pad 612 and GND1 bond pad 614. Similarly, second die 620 can include at least two bond pads, here shown as a VCC2 bond pad 622 and GND2 bond pad 624. A first ESD clamp 618 can be provided on the first die 610 between bond pads 612, 614 and a second ESD clamp 628 can be provided on the second die 620 between bond pads 622, 624, as shown.

Die 610, 620 can be mounted to a lead frame 660 that has leads for making electrical connection to the IC 600 in assembly. To this end, die 620 can be mechanically secured to a die attach paddle of lead frame 660 and the die 610 can be mechanically secured to the die 620. A non-conductive, electrically insulative adhesive 674 can be provided between the second die 620 and the lead frame 660 and a similar layer 670 can be provided between the first die 610 and the second die 620. Multi-die device 600 can be described as a “stacked” configuration of die 610, 620 in which the die vertically overlap one another.

Electrical connection between die 610, 620 and lead frame 660 can be achieved with wire bonds as shown or with solder balls or solder bumps in some configurations. Device 600 can further include a package body enclosing a portion of the lead frame 660, the first die 610, and the second die 620. The package body can be in the form of various package types, such as a so-called Thin Shrink Small Outline Package (i.e., TSSOP). It will be appreciated by those of ordinary skill in the art, however, that the concepts described herein are not limited to any particular package type or number or configuration of leads.

In assembly as shown, the first TSV 630 and the second TSV 640 are aligned (e.g., vertically aligned) to form spark gap 638 (represented by a conduction path line labeled 638) between the first die 610 and the second die 620.

Die 610 and 620 can be attached to each other with an adhesive layer 670. Adhesive layer 670 may or may not be disposed between the first and second TSV 630, 640. In the example of FIG. 6, the adhesive layer 670 is not disposed between the first and second TSV 630, 640. Thus, in this example, spark gap 638 includes air between the TSVs 630, 640 and the breakdown voltage required to permit conduction through the illustrated spark gap 638 includes the breakdown of air.

In other embodiments in which adhesive layer 670 is disposed in the area between the first and second TSVs 630, 640, spark gap 638 includes a portion 670a of the adhesive layer 670 between the TSVs. In such embodiments, the breakdown voltage required to permit conduction through the illustrated spark gap 638 includes the breakdown of the adhesive layer material. For example, in embodiments in which adhesive layer portion 670a is disposed between TSVs 630, 640, a maximum breakdown voltage of the adhesive material can be on the order of 2 kV to permit current conduction.

In use, an ESD or other electrical overstress condition can occur and by operation of the spark gap 638, current (represented by conduction path line labeled 638) can conduct from the bond pad 614, through TSV 630, to TSV 640 (either through air or adhesive layer portion 670a), and out of the IC 600 through the bond pad 624. It will be appreciated that other conduction paths are possible of which the illustrated path through spark gap 638 is an example.

According to an aspect of the disclosure, a thickness of a adhesive layer portion 670a disposed between TSVs 630, 640 can be monitored based on a breakdown voltage that causes an arc across the spark gap 638. Since the permittivity of the adhesive layer material is known, a voltage can be applied (e.g., at bond pad 614) and increased until conduction through spark gap 638 occurs. Based on the applied voltage that initiates conduction through spark gap 638, the thickness of adhesive layer portion 670a can be determined.

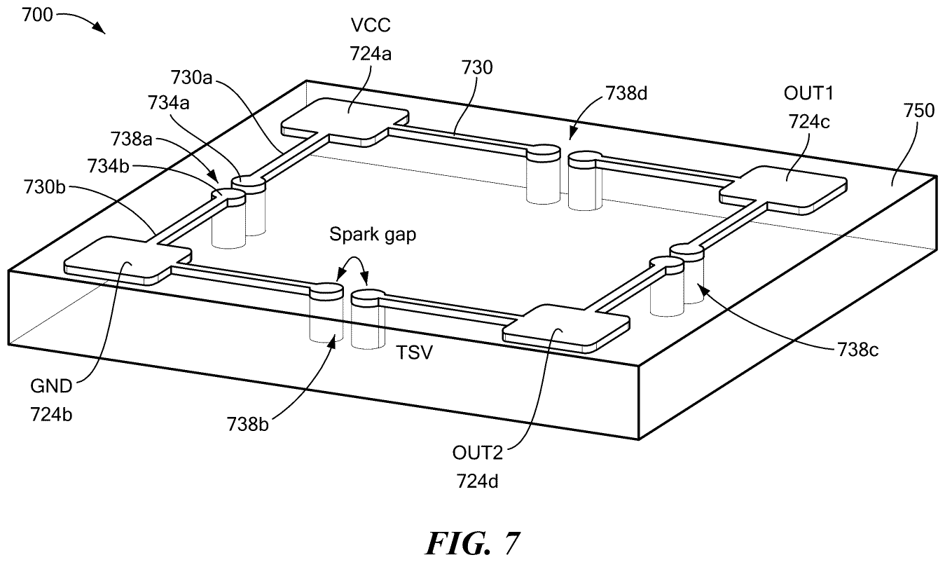

Referring to FIG. 7, a perspective view of an integrated circuit device 700 includes a plurality of spark gaps 738a, 738b, 738c, 738d, each formed between adjacent TSVs that extend from a top metal layer 730 on a top surface of the device substrate to a bottom surface of the substrate. Metal layer 730 includes metal portions configured to be coupled to spark gaps 738a, 738b, 738c, 738d, to bond pads 724a, 724b, 724c, 724d, and to circuitry supported by the substrate.

Bond pads 724a, 724b, 724c, 724d permit electrical connection and probe contact to device 700. Example bond pads include VCC bond pad 724a and GND bond pad 724b through which power is coupled to the device 700. Example bond pad 724c can provide a first output connection OUT1 and example bond pad 724d can provide a second output connection OUT2, with output connection bond pads 724c, 724d permitting communication of device output signals to external circuits and systems.

As is labeled in connection with spark gap 738a, metal layer 730 includes a first metal portion 730a configured to be coupled to first bond pad 724a and a second metal portion 730b configured to be coupled to second bond pad 724b. Metal portion 730a can have a terminal end in the form of a TSV 734a and metal portion 730b can have a terminal end in the form of a TSV 734b.

Spark gap 738a can take the form of a gap between adjacent TSVs 734a, 734b. The gap between the top, adjacent surfaces of TSVs 734a, 734b can be on the same order as the gaps in FIGS. 1A, 2, and 3 for example.

In use, an ESD or other electrical overstress condition can occur and by operation of the spark gap 738a, current can conduct from the bond pad 724a, through metal portion 730a, to a top of TSV 734a, through the airgap between the top of TSV 734a to the top of TSV 734b, through metal portion 730b and out of the IC 700 through the bond pad 724a. It will be appreciated by those of ordinary skill in the art that other conduction paths are possible of which the described path through spark gap 738a is an example.

A passivation layer 750 may or may not have an opening to expose the tops of TSVs forming spark gap 738a. Thus, in embodiments in which passivation layer 750 has an opening to expose the top, adjacent surfaces of TSVs 734a, 734b, the spark gap 738a includes air and in embodiments that do not include an opening in the passivation layer, the spark gap 738a includes the passivation layer material.

It will be appreciated that spark gaps 738a, 738b, 738c, 738d can be the same as each other or can be different in design. It will also be appreciated that device 700 is an example only and that the configuration of bond pads 724a, 724b, 724c, 724d, top metal layer 730, and spark gaps 738a, 738b, 738c, 738d can be varied to suit application requirements.

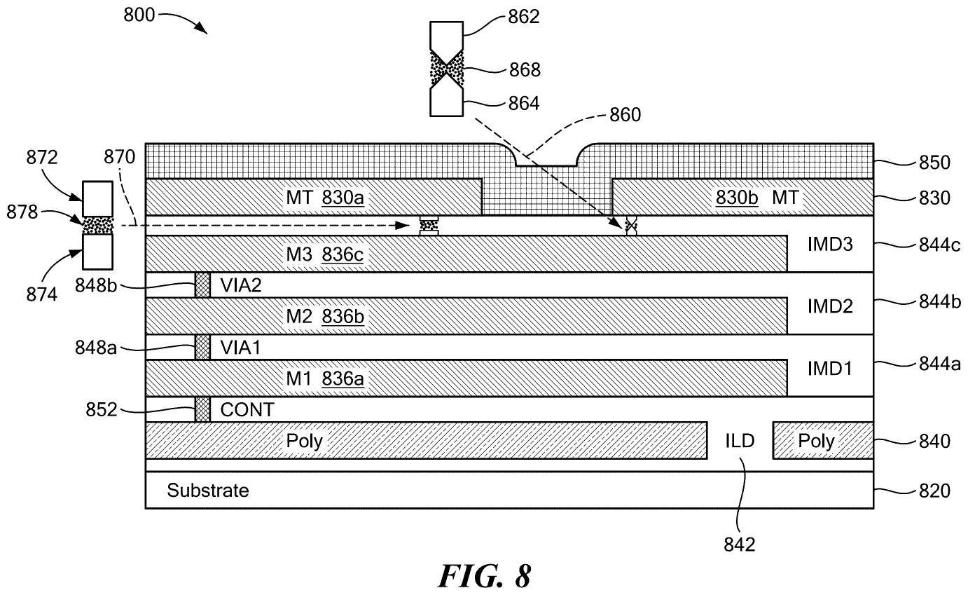

Referring to FIG. 8, a cross-sectional side view of an integrated circuit device 800 shows a substrate 820 and a metal layer 830 disposed over the substrate. The metal layer 830 includes a first metal portion 830a configured to be coupled to a first bond pad (e.g., as shown in FIG. 4) and a second metal portion 830b configured to be coupled to a second bond pad (e.g., as shown in FIG. 4).

Similar to metal layer 30 of FIG. 1, metal layer 830 can be a top metal layer, MT, and additional metal layers of device 800 can include a first metal layer M1 836a, a second metal layer M2 836b, a third metal layer M3 836c, as shown. Dielectric layers 844a, 844b, 844c are disposed between each of the metal layers 30, 36a, 36b, and 36c, as shown, and may be the same as or similar to dielectric layers 44a, 44b, 44c of FIG. 1. A polysilicon layer 840 and an interlayer dielectric (ILD) 842 can be similar to layers 40, 42 of FIG. 1. Polysilicon layer 840 can be coupled to the first metal layer 836a by a contact element 852 and vias 848a, 848b can be coupled between the metal layers 836a, 836b, 836c, as shown. A passivation layer 850 can be disposed over the top metal layer 830.

Device 800 can include a vertical spark gap including vias 860, 870 that contain controllable dielectric materials. Each of the vias 860, 870 includes one or more metal portions and a dielectric portion.

Via 860 includes a first metal portion 862 that can be in contact with metal portion 830b and a second metal portion 864 that can be in contact with metal layer 836c and a dielectric 868 disposed between metal portions 862, 864. A gap between metal portions 862, 864 forms a spark gap.

Similarly, via 870 includes a first metal portion 872 that can be in contact with metal portion 830a and a second metal portion 874 that can be in contact with metal layer 836c and a dielectric 878 disposed between metal portions 872, 874. A gap between metal portions 872, 874 forms a spark gap.

The breakdown voltage associated with vias 860, 870 can be controlled by design of the terminal ends of the metal portions 862, 864 and 872, 874 associated with the vias and the length of the respective gap and the material of dielectric 868, 878. For example, metal portions 862, 864 of via 860 are generally pointed in shape and of metal portions 872, 874 of via 870 are generally flat in shape. Thus, the gap length and the shape of metal portions 862, 864 of via 860 and of metal portions 872, 874 of via 870 can be varied in order to achieve a desired breakdown voltage.

In use, when the voltage between metal portions 830a, 830b of top metal layer 830 reaches a breakdown voltage associated with vias 860, 870, current flows from first metal portion 830a through via 870 to metal layer 836c, through via 860 and to second metal portion 830b and continues to flow until the voltage drops to below the breakdown voltage. Without the described spark gap including TSVs 860, 870, current could flow internally to device 800 and potentially damage electronic circuitry supported by the substrate 820.

As used herein, the term “magnetic field sensing element” is used to describe a variety of electronic elements that can sense a magnetic field. The magnetic field sensing element can be, but is not limited to, a Hall effect element, a magnetoresistance element, a magnetotransistor, or an inductive coil. As is known, there are different types of Hall effect elements, for example, a planar Hall element, a vertical Hall element, and a Circular Vertical Hall (CVH) element. As is also known, there are different types of magnetoresistance elements, for example, a semiconductor magnetoresistance element such as Indium Antimonide (InSb), a giant magnetoresistance (GMR) element, for example, a spin valve, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb).

As is known, some of the above-described magnetic field sensing elements tend to have an axis of maximum sensitivity parallel to a substrate or in the plane of the substrate that supports the magnetic field sensing element, and others of the above-described magnetic field sensing elements tend to have an axis of maximum sensitivity perpendicular to a substrate that supports the magnetic field sensing element. In particular, planar Hall elements tend to have axes of maximum sensitivity perpendicular to a substrate, while metal based or metallic magnetoresistance elements (e.g., GMR, TMR, AMR) and vertical Hall elements tend to have axes of maximum sensitivity parallel to a substrate.

As used herein, the term “predetermined,” when referring to a value or signal, is used to refer to a value or signal that is set, or fixed, in the factory at the time of manufacture, or by external means, e.g., programming, thereafter. As used herein, the term “determined,” when referring to a value or signal, is used to refer to a value or signal that is identified by a circuit during operation, after manufacture.

Also, the following definitions and abbreviations are to be used for the interpretation of the claims and the specification. The terms “comprise,” “comprises,” “comprising,” “include,” “includes,” “including,” “has,” “having,” “contains” or “containing,” or any other variation are intended to cover a non-exclusive inclusion. For example, an apparatus, a method, a composition, a mixture, or an article, that includes a list of elements is not necessarily limited to only those elements but can include other elements not expressly listed or inherent to such apparatus, method, composition, mixture, or article.

References in the specification to “embodiments,” “one embodiment, “an embodiment,” “an example embodiment,” “an example,” “an instance,” “an aspect,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it may affect such feature, structure, or characteristic in other embodiments whether explicitly described or not.

It is noted that various connections and positional relationships (e.g., over, below, adjacent, etc.) may be used to describe elements and components in the description and drawings. These connections and/or positional relationships, unless specified otherwise, can be direct or indirect, and the described concepts, systems, devices, structures, and techniques are not intended to be limiting in this respect. Accordingly, a coupling of entities can refer to either a direct or an indirect coupling, and a positional relationship between entities can be a direct or indirect positional relationship. As an example of an indirect positional relationship, positioning element “A” over element “B” can include situations in which one or more intermediate elements (e.g., element “C”) is between elements “A” and elements “B” as long as the relevant characteristics and functionalities of elements “A” and “B” are not substantially changed by the intermediate element(s).

In the foregoing detailed description, various features of embodiments are grouped together in one or more individual embodiments for the purpose of streamlining the disclosure. This method of disclosure is not to be interpreted as reflecting an intention that the claims require more features than are expressly recited therein. Rather, inventive aspects may lie in less than all features of each disclosed embodiment. Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

Having described preferred embodiments of the present disclosure, it will now become apparent to one of ordinary skill in the art that other embodiments incorporating their concepts may be used. It is felt therefore that these embodiments should not be limited to disclosed embodiments, but rather should be limited only by the spirit and scope of the appended claims.

1. Apparatus comprising:
a substrate;
a metal layer disposed over the substrate and including a first metal portion coupled to a first bond pad and having a first terminal end and a second metal portion coupled to a second bond pad and having a second terminal end spaced from the first terminal end by a gap configured to form a spark gap between the first terminal end and the second terminal end; and
a passivation layer disposed over the metal layer.

2. The apparatus of claim 1 wherein the passivation layer has an opening configured to expose the first terminal end and the second terminal end to air, wherein the spark gap extends through air.

3. The apparatus of claim 1 wherein the spark gap extends through a portion of the passivation layer disposed between the first terminal end and the second terminal end.

4. The apparatus of claim 1 wherein the metal layer comprises a plurality of metal layers including a top metal layer positioned further from the substrate than the other metal layers, wherein the first metal portion and the second metal portion are portions of the top metal layer.

5. The apparatus of claim 1 wherein the first terminal end has a first point and the second terminal end has a second point.

6. The apparatus of claim 5 wherein the first terminal end has a plurality of first points and the second terminal end has a plurality of second points, wherein each of the first points is spaced from a respective second point by a gap configured to form a spark gap between the respective first point and second point.

7. The apparatus of claim 6 wherein at least two of the gaps between first and second points have different lengths.

8. The apparatus of claim 1 wherein the first terminal end has a first rounded edge and the second terminal end has a second rounded edge.

9. The apparatus of claim 8 wherein the first terminal end has a plurality of first rounded edges and the second terminal end has a plurality of second rounded edges, wherein each of the first rounded edges is spaced from a respective second rounded edge by a gap configured to form a spark gap between the respective first and second rounded edges.

10. The apparatus of claim 9 wherein at least two of the gaps between first and second rounded edges have different lengths.

11. The apparatus of claim 1 wherein the first terminal end has a point and the second terminal end has a concave edge.

12. The apparatus of claim 1 wherein the apparatus comprises an integrated circuit package and the substrate comprises a semiconductor die.

13. The apparatus of claim 12 wherein the first metal portion is attached to a first bond pad of the integrated circuit package and the second metal portion is attached to a second bond pad of the integrated circuit package.

14. The apparatus of claim 1 wherein the spark gap comprises a first spark gap and wherein the substrate comprises:
a first die having a first ground contact and a first Through Silicon Via (TSV) extending from a top surface of the first die to a bottom surface of the first die; and
a second die having a second ground contact that is galvanically isolated from the first ground contact and having a second TSV extending from a top surface of the second die to a bottom surface of the second die, wherein the first TSV and the second TSV are vertically aligned to form a second spark gap between the first die and the second die.

15. The apparatus of claim 14 further comprising an adhesive layer between the bottom surface of the first die and the top surface of the second die.

16. The apparatus of claim 15 wherein the adhesive layer is disposed between the first TSV and the second TSV.

17. The apparatus of claim 15 wherein the adhesive layer is not disposed between the first TSV and the second TSV.

18. Apparatus comprising:
a first die having a first ground contact and a first Through Silicon Via (TSV) extending from a top surface of the first die to a bottom surface of the first die; and
a second die having a second ground contact that is galvanically isolated from the first ground contact and a second TSV extending from a top surface of the second die to a bottom surface of the second die, wherein the first TSV and the second TSV are vertically aligned to form a spark gap between the first die and the second die.

19. The apparatus of claim 18 further comprising an adhesive layer between the bottom surface of the first die and the top surface of the second die.

20. The apparatus of claim 19 wherein the adhesive layer is disposed between the first TSV and the second TSV.

21. The apparatus of claim 19 wherein the adhesive layer is not disposed between the first TSV and the second TSV.

22. A method for protecting an integrated circuit from electrostatic discharge comprising:
providing a substrate;
providing a metal layer over the substrate with a first metal portion coupled to a first bond pad and having a first terminal end and a second metal portion coupled to a second bond pad and having a second terminal end spaced from the first terminal end by a gap configured to form a spark gap between the first terminal end and the second terminal end; and
providing a passivation layer over the metal layer.

23. The method of claim 22 further comprising forming an opening in the passivation layer to expose the first terminal end and the second terminal end to air, wherein the spark gap extends through air.

24. The method of claim 22 wherein the spark gap extends through a portion of the passivation layer disposed between the first terminal end and the second terminal end.

25. A method for protecting a multi-die electronic device from electrostatic discharge comprising:
providing a first die having a first ground contact and a first TSV extending from a top surface of the first die to a bottom surface of the first die;
providing a second die having a second ground contact that is galvanically isolated from the first ground contact and a second TSV extending from a top surface of the second die to a bottom surface of the second die; and
attaching a second die to the first die so that the first TSV is vertically aligned with the second TSV to form a spark gap between the first die and the second die.

26. The method of claim 25 further comprising providing an adhesive layer between the first die and the second die.

27. The method of claim 26 further comprising monitoring a thickness of the adhesive layer based on a breakdown voltage that causes an arc across the spark gap.

28. Apparatus comprising:
a substrate;
a bottom metal layer disposed over the substrate;
a top metal layer disposed over the bottom metal layer and including a first metal portion coupled to a first bond pad and having a first terminal end and a second metal portion coupled to a second bond pad and having a second terminal end spaced from the first terminal end by a gap;
a dielectric layer between the top metal layer and the bottom metal layer;
a first via between the first metal portion of the top metal layer and the bottom metal layer and including a metal via portion and a dielectric via portion;
a second via between the second metal portion of the top metal layer and the bottom metal layer and including a metal via portion and a dielectric via portion; and
a passivation layer disposed over the top metal layer.
